(19) United States
(12) Patent Application Publication
(10) Pub. No.: US 2026/0282959 A1
(43) Pub. Date: Sep. 17, 2026

(54) PACKAGE STRUCTURE AND METHOD FOR FORMING THE SAME

(71) Applicant: JCET Microelectronics (Jiangyin) Co., LTD., Jiangyin (CN)

(72) Inventors: Haijie CHEN, Jiangyin (CN); Jingyu WU, Jiangyin (CN)

(73) Assignee: JCET Microelectronics (Jiangyin) Co., LTD., Jiangyin (CN)

(21) Appl. No.: 19/565,100

(22) Filed: Mar. 12, 2026

(30) Foreign Application Priority Data
Mar. 14, 2025 (CN) 202510301491.1

(51) Int. Cl. H10W 70/63; H10W 20/20; H10W 70/05; H10W 70/60; H10W 90/00; H10W 90/15; H10W 90/22

(52) U.S. Cl. CPC H10W 70/635; H10W 20/211; H10W 70/095; H10W 70/618; H10W 90/15; H10W 90/22; H10W 90/724; H10W 90/794

(57) ABSTRACT

A package structure and a method for forming the same are provided. The package structure includes: an interposer including a first main surface and a second main surface opposed to the first main surface along a first direction; a first chip on the first main surface, and the first chip is electrically connected to the interposer; a storage structure on the first main surface, and the storage structure is electrically connected to the interposer, and the storage structure and the first chip are arranged along a second direction; and a second chip on the second main surface, and the second chip is electrically connected to the interposer, and a projection of the second chip on the second main surface covers a projection of the first chip on the second main surface and a projection of the storage structure on the second main surface.

### CROSS-REFERENCE TO RELATED APPLICATIONS

This application claims the benefit of priority to Chinese Application No. 202510301491.1, filed Mar. 14, 2025, which is incorporated herein by reference in its entirety.

### TECHNICAL FIELD

The present disclosure relates to the field of semiconductor manufacturing technology, and particularly relates to a package structure and a method for forming the same.

### BACKGROUND

Currently, the semiconductor integrated circuit (IC) industry has experienced exponential growth. Technological advancements in IC materials and design have yielded a plurality of generations of ICs, wherein each generation of IC has smaller and more complex circuits than the previous generation of IC. In the process of IC development, functional density (i.e., the number of interconnected devices per chip area) has generally increased, while geometric dimensions (i.e., the smallest components that can be produced using manufacturing processes) have continuously decreased. By using interposers, a plurality of heterogeneous or homogeneous chips can be interconnected and signal transmission can be achieved, so that the integration of microsystems is ultimately achieved.

### SUMMARY

The present disclosure provides a package structure and a method for forming the same for integrating storage structures with other chips within a limited space to expand the functionality of the package structure while simultaneously improving the heat dissipation performance of the package structure, thereby achieving the improvement and expansion of the package structure performance.

According to some embodiments, the present disclosure provides a package structure, which includes: an interposer including a first main surface and a second main surface distributed opposed to each other along a first direction; a first chip located on the first main surface of the interposer, and the first chip is electrically connected with the interposer; a storage structure located on the first main surface of the interposer, and the storage structure is electrically connected with the interposer, and the storage structure and the first chip are arranged along a second direction, and the second direction intersects perpendicularly with the first direction; and a second chip located on the second main surface of the interposer, and the second chip is electrically connected with the interposer, and the projection of the second chip on the second main surface covers the projection of the first chip on the second main surface and the projection of the storage structure on the second main surface.

In some embodiments, the second chip includes a front surface and a back surface distributed opposed to each other along the first direction, the functional area of the second chip is located on the front surface of the second chip; and the second chip is hybrid bonded on the second main surface of the interposer, and the front surface of the second chip faces the interposer.

In some embodiments, the package structure further includes: a first vertical interconnection structure passing through the interposer at least along the first direction, one end of the first vertical interconnection structure is electrically connected with the first chip and another end is electrically connected with the second chip; and a second vertical interconnection structure passing through the interposer at least along the first direction, one end of the second vertical interconnection structure is electrically connected with the storage structure and another end is electrically connected with the second chip.

In some embodiments, the first vertical interconnection structure includes a first conductive connection pillar passing through the interposer along the first direction, a first solder pad located on a side of the first conductive connection pillar facing the first chip, a first internal interconnection solder ball located on the first solder pad; and a first metal layer located on a side of the first conductive connection pillar facing the second chip, and the first internal interconnection solder ball is electrically connected with the first chip; and the second vertical interconnection structure includes a second conductive connection pillar passing through the interposer along the first direction, a second solder pad located on a side of the second conductive connection pillar facing the storage structure, a second internal interconnection solder ball located on the second solder pad, and a second metal layer located on a side of the second conductive connection pillar facing the second chip, and the second internal interconnection solder ball is electrically connected with the storage structure.

In some embodiments, the package structure further includes: a bonding dielectric layer covering the second main surface of the interposer, the first metal layer and the second metal layer are located within the bonding dielectric layer.

In some embodiments, the package structure further includes: a third vertical interconnection structure continuously passing through the interposer, the bonding dielectric layer, and the second chip at least along the first direction, and the third vertical interconnection structure is electrically connected with the first chip; and a fourth vertical interconnection structure continuously passing through the interposer, the bonding dielectric layer, and the second chip at least along the first direction, and the fourth vertical interconnection structure is electrically connected with the storage structure.

In some embodiments, the third vertical interconnection structure includes a third conductive connection pillar passing through the interposer, the bonding dielectric layer and the second chip along the first direction, a third solder pad located on a side of the third conductive connection pillar facing the first chip, a third internal interconnection solder ball located on the third solder pad, and a first lead out solder ball located on the surface of a side of the second chip facing away from the interposer; and the fourth vertical interconnection structure includes a fourth conductive connection pillar passing through the interposer, the bonding dielectric layer, and the second chip along the first direction, a fourth solder pad located on a side of the fourth conductive connection pillar facing the storage structure, a fourth internal interconnection solder ball located on the fourth solder pad, and a second lead out solder ball located on the surface of a side of the second chip facing away from the interposer.

In some embodiments, the package structure further includes: a first internal interconnection structure including a fifth solder pad located on the first main surface of the interposer and a fifth internal interconnection solder ball located on the fifth solder pad, the fifth solder pad is electrically connected with the line layer and the fifth internal interconnection solder ball is electrically connected with the first chip; and a second internal interconnection structure including a sixth solder pad located on the first main surface of the interposer and a sixth internal interconnection solder ball located on the sixth solder pad, the sixth solder pad is electrically connected with the line layer and the sixth internal interconnection solder ball is electrically connected with the storage structure.

In some embodiments, the package structure further includes: a third chip located on the first main surface of the interposer, the first chip, the third chip, and the storage structure are arranged along a direction parallel to the first main surface, and the projection of the second chip on the second main surface continuously covers the projection of the first chip on the second main surface, the projection of the third chip on the second main surface, and the projection of the storage structure on the second main surface.

In some embodiments, the package structure further includes: a molding layer located on the first main surface of the interposer, and the molding layer continuously molds the first chip and the storage structure.

In some embodiments, the surface of the first chip facing away from the interposer along the first direction is flush with the surface of the storage structure facing away from the interposer along the first direction.

In some embodiments, the molding layer exposes the surface of the first chip facing away from the interposer and the surface of the storage structure facing away from the interposer.

In some embodiments, the storage structure is a high bandwidth memory.

According to other embodiments, the present disclosure also provides a method for forming a package structure, which includes the following steps: forming an interposer, the interposer includes a first main surface and a second main surface distributed opposed to each other along a first direction; and connecting a second chip onto the second main surface of the interposer, and electrically connecting a first chip and a storage structure onto the first main surface of the interposer, the storage structure and the first chip are arranged along a second direction, and the first chip, the second chip, and the storage structure are all electrically connected with the interposer, and the projection of the second chip on the second main surface covers the projection of the first chip on the second main surface and the projection of the storage structure on the second main surface, and the second direction intersects perpendicularly with the first direction.

In some embodiments, the specific steps for connecting a second chip onto the second main surface of the interposer, and electrically connecting a first chip and a storage structure onto the first main surface of the interposer include: connecting the second chip onto the second main surface of the interposer, and electrically connecting the first chip, the third chip, and the storage structure onto the first main surface of the interposer, the first chip, the third chip, and the storage structure are arranged along a direction parallel to the first main surface, and the projection of the second chip on the second main surface continuously covers the projection of the first chip on the second main surface, the projection of the third chip on the second main surface, and the projection of the storage structure on the second main surface.

In some embodiments, before connecting a second chip onto the second main surface of the interposer, and electrically connecting a first chip and a storage structure onto the first main surface of the interposer, the method further includes the following steps: forming a first solder pad and a second solder pad located on the first main surface of the interposer and a first conductive connection pillar and a second conductive connection pillar passing through the interposer along the first direction, the first conductive connection pillar is electrically connected with the first solder pad and the second conductive connection pillar is electrically connected with the second solder pad; and forming, on the second main surface of the interposer, a bonding dielectric layer and a first metal layer and a second metal layer passing through the bonding dielectric layer along the first direction, the first metal layer is electrically connected with the first conductive connection pillar, and the second metal layer is electrically connected with the second conductive connection pillar.

In some embodiments, the specific steps for forming a first solder pad and a second solder pad located on the first main surface of the interposer and a first conductive connection pillar and a second conductive connection pillar passing through the interposer along the first direction, the first conductive connection pillar is electrically connected with the first solder pad and the second conductive connection pillar is electrically connected with the second solder pad include: providing an interposer; forming a first blind hole and a second blind hole arranged along the second direction within the interposer, and both the first blind hole and the second blind hole extend from the first main surface of the interposer toward the interior of the interposer; forming a first conductive connection pillar within the first blind hole and forming a second conductive connection pillar within the second blind hole; and forming, on the first main surface of the interposer, a first solder pad electrically connected with the first conductive connection pillar and a second solder pad electrically connected with the second conductive connection pillar; and thinning the interposer to expose the surface of the first conductive connection pillar facing away from the first solder pad and the surface of the second conductive connection pillar facing away from the second solder pad.

In some embodiments, the second chip includes a front surface and a back surface distributed opposed to each other along the first direction, and the functional area of the second chip is located on the front surface of the second chip; the specific steps for connecting the second chip onto the second main surface of the interposer and electrically connecting the first chip and the storage structure onto the first main surface of the interposer include: hybrid bonding the second chip with the interposer in a direction in which the front surface of the second chip faces the bonding dielectric layer; and soldering the first chip and the storage structure onto the first main surface of the interposer.

In some embodiments, before soldering the first chip and the storage structure onto the first main surface of the interposer, the method further includes the following steps: forming a third vertical interconnection structure and a fourth vertical interconnection structure both continuously passing through the interposer, the bonding dielectric layer, and the second chip along the first direction, and the third vertical interconnection structure and the fourth vertical interconnection structure are arranged at intervals along the second direction.

In some embodiments, the first main surface of the interposer is also provided with a third solder pad and a fourth solder pad; the specific steps for forming the third vertical interconnection structure and the fourth vertical interconnection structure both continuously passing through the interposer, the bonding dielectric layer, and the second chip along the first direction include: forming a third conductive connection pillar sequentially passing through the second chip, the bonding dielectric layer, and the interposer along the first direction and electrically connected with the third solder pad, and forming a fourth conductive connection pillar sequentially passing through the second chip, the bonding dielectric layer, and the interposer along the first direction and electrically connected with the fourth solder pad, to form the third vertical interconnection structure including the third solder pad and the third conductive connection pillar, and to form the fourth vertical interconnection structure including the fourth solder pad and the fourth conductive connection pillar.

In some embodiments, the specific steps for forming a third conductive connection pillar sequentially passing through the second chip, the bonding dielectric layer and the interposer along the first direction and electrically connected with the third solder pad, and forming a fourth conductive connection pillar sequentially passing through the second chip, the bonding dielectric layer and the interposer along the first direction and electrically connected with the fourth solder pad include: etching starting from the surface of the second chip facing away from the interposer, forming a first through-hole sequentially passing through the second chip, the bonding dielectric layer and the interposer along the first direction and exposing the third solder pad, and forming a second through-hole sequentially passing through the second chip, the bonding dielectric layer and the interposer along the first direction and exposing the fourth solder pad; and filling conductive material into the first through-hole and the second through-hole, forming the third conductive connection pillar within the first through-hole, and forming the fourth conductive connection pillar within the second through-hole.

In some embodiments, before soldering the first chip and the storage structure onto the first main surface of the interposer, the method further includes the following steps: forming a first lead out solder ball located on a surface of the third conductive connection pillar facing away from the third solder pad, and forming a second lead out solder ball located on a surface of the fourth conductive connection pillar facing away from the fourth solder pad.

In some embodiments, the first main surface of the interposer is also provided with a fifth solder pad and a sixth solder pad electrically connected with the interposer; the specific steps for soldering the first chip and the storage structure onto the first main surface of the interposer include: forming a first internal interconnection solder ball, a third internal interconnection solder ball and a fifth internal interconnection solder ball on the surface of the first chip, and forming a second internal interconnection solder ball, a fourth internal interconnection solder ball and a sixth internal interconnection solder ball on the surface of the storage structure; and soldering the first chip and the storage structure onto the first main surface of the interposer, such that the first internal interconnection solder ball on the first chip is soldered to the first pad, the third internal interconnection solder ball is soldered to the third solder pad, and the fifth internal interconnection solder ball is soldered to the fifth solder pad, and such that the second internal interconnection solder ball on the storage structure is soldered to the second solder pad, the fourth internal interconnection solder ball is soldered to the fourth solder pad, and the sixth internal interconnection solder ball is soldered to the sixth solder pad.

In some embodiments, the surface of the first chip facing away from the interposer is flush with the surface of the storage structure facing away from the interposer.

In some embodiments, after soldering the first chip and the storage structure onto the first main surface of the interposer, the method further includes the following steps: forming, on the first main surface of the interposer, a molding layer continuously molding the first chip and the storage structure, the molding layer exposes the surface of the first chip facing away from the interposer and the surface of the storage structure facing away from the interposer.

In some embodiments, after forming a molding layer continuously molding the first chip and the storage structure on the first main surface of the interposer, the method further includes the following steps: forming a first lead out solder ball located on a surface of the third conductive connection pillar facing away from the third solder pad, and forming a second lead out solder ball located on a surface of the fourth conductive connection pillar facing away from the fourth solder pad.

### BRIEF DESCRIPTION OF THE DRAWINGS

FIG. 1 is a structural schematic diagram of a package structure in an embodiment of the present disclosure;

FIG. 2 is a structural schematic diagram of an interposer before mounting the first chip and storage structure in an embodiment of the present disclosure;

FIG. 3 is a flowchart of a method for forming a package structure in an embodiment of the present disclosure;

FIG. 4 is a structural schematic diagram of an interposer in an embodiment of the present disclosure;

FIG. 5 is a structural schematic diagram after forming the first vertical interconnection structure and the second vertical interconnection structure in an embodiment of the present disclosure;

FIG. 6 is a structural schematic diagram after bonding the second chip to the second main surface of the interposer in an embodiment of the present disclosure;

FIG. 7 is a structural schematic diagram after forming the first through-hole and the second through-hole in an embodiment of the present disclosure;

FIG. 8 is a structural schematic diagram after forming the third vertical interconnection structure and the fourth vertical interconnection structure in an embodiment of the present disclosure;

FIG. 9 is a structural schematic diagram of the first chip in an embodiment of the present disclosure;

FIG. 10 is a structural schematic diagram of the storage structure in an embodiment of the present disclosure; and

FIG. 11 is a structural schematic diagram after mounting the first chip and the storage structure onto the first main surface of the interposer in an embodiment of the present disclosure.

### DETAILED DESCRIPTION

The embodiments of the package structure and the method for forming the same provided by the present disclosure are described in detail below in conjunction with the accompanying drawings.

In the 2.5D package structure, it is necessary to integrate more and more functions within a limited space to solve the challenges in the production process. However, in the current 2.5D structure, a tiled manner is mostly used to integrate a plurality of chips, resulting in a larger size of the final formed package structure. Moreover, when the number of chips integrated into the package structure increases, the heat dissipation performance of the package structure will be affected, thereby resulting in a decrease in the service life of the package structure. Moreover, integrating storage structures with other chips is also a hotspot of current research.

Therefore, an urgent technical problem that needs to be solved is, how to integrate storage structures with other chips within a limited space to expand the functionality of the package structure while simultaneously improving the heat dissipation performance of the package structure, and achieve the improvement and expansion of the package structure performance.

In the package structure and the method for forming the same provided by the present disclosure, by mounting the first chip and the storage structure on the first main surface of the interposer and arranging the second chip on the second main surface of the interposer, and making the projection of the second chip on the second main surface cover the projection of the first chip on the second main surface and the projection of the storage structure on the second main surface, not only the integration of a plurality of chips and storage structures is achieved within a limited space, and the integration degree and scalability of the package structure are also improved, and the functionality of the package structure is expanded, but also by arranging the second chip with the largest area on the second main surface, the area of the entire package structure is effectively saved, thereby helping to further reduce the size of the package structure. Meanwhile, the first chip and the second chip are arranged on opposite sides of the interposer in the present disclosure, so that heat dissipation can be carried out from the opposite two sides of the interposer, respectively, the overall heat dissipation performance of the package structure is improved, which helps to further extend the service life of the package structure.

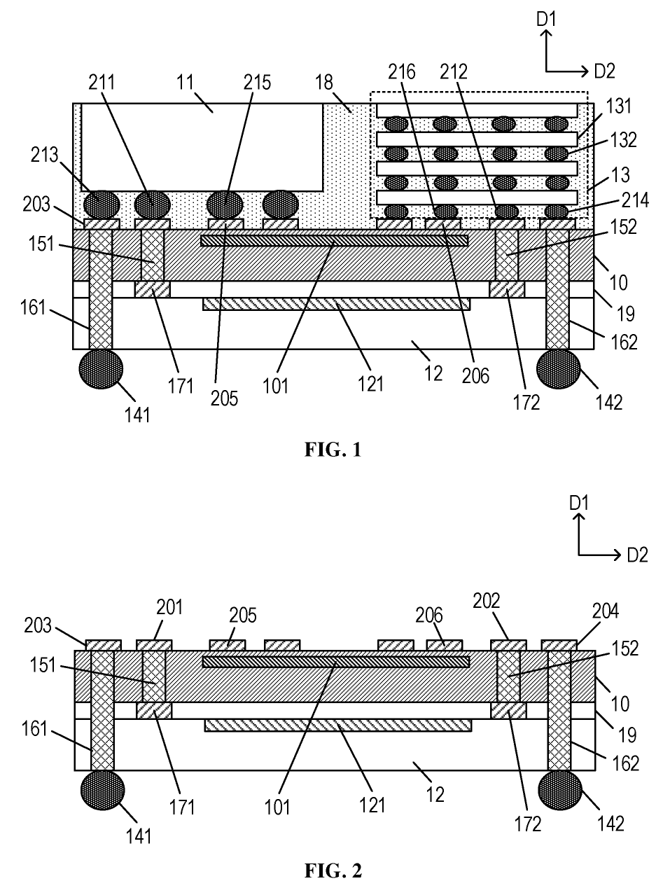

The embodiments in the present disclosure provide a package structure. FIG. 1 is a structural schematic diagram of a package structure in an embodiment of the present disclosure, and FIG. 2 is a structural schematic diagram of an interposer before mounting the first chip and storage structure in an embodiment of the present disclosure. As shown in FIGS. 1 and 2, the package structure includes: an interposer 10, including a first main surface and a second main surface distributed opposed to each other along a first direction D1; a first chip 11, located on the first main surface of the interposer 10, and the first chip 11 is electrically connected with the interposer 10; a storage structure 13, located on the first main surface of the interposer 10, and the storage structure 13 is electrically connected with the interposer 10, and the storage structure 13 and the first chip 11 are arranged along a second direction D2, and the second direction D2 intersects perpendicularly with the first direction D1; and a second chip 12, located on the second main surface of the interposer 10, and the second chip 12 is electrically connected with the interposer 10, and the projection of the second chip 12 on the second main surface covers the projection of the first chip 11 on the second main surface and the projection of the storage structure 13 on the second main surface.

In some embodiments, the interposer 10 includes an interposer body and a line layer 101 located within the interposer body, and the top surface of the interposer body serves as the first main surface of the interposer 10, and the bottom surface of the interposer body serves as the second main surface of the interposer 10. Wherein the material of the interposer body may be silicon, glass, or organic polymer material. The line layer 101 is a high-density wiring layer arranged inside the interposer body. The material of the line layer 101 may be a metallic conductive material such as copper, etc. In one example, the interposer body includes multiple insulating dielectric layers stacked in sequence along the first direction D1, and the line layer 101 is distributed within the multiple insulating dielectric layers. The first chip 11 and the storage structure 13 are mounted on the first main surface of the interposer 10, and the storage structure 13 and the first chip 11 are arranged along the second direction D2, i.e., the storage structure 13 and the first chip 11 are tiled on the first main surface of the interposer 10. The second chip 12 is mounted on the second main surface of the interposer 10, i.e., the first chip 11 and the second chip 12 are arranged along a vertical direction. In one example, the first chip 11 is flip-chip mounted on the first main surface of the interposer 10, i.e., the functional side of the first chip 11 faces the first main surface of the interposer 10.

In some embodiments, the storage structure 13 is a high bandwidth memory (HBM). For example, the storage structure 13 includes a plurality of memory chips 131 stacked in sequence along the first direction D1 and conductive connection structures 132 located between adjacent memory chips 131, and the conductive connection structures 132 are used to electrically connect adjacent memory chips 131. Wherein the memory chips 131 may be DRAM (Dynamic Random Access Memory).

In the present embodiment, by arranging the second chip 12 on the side of the interposer 10 facing away from the first chip 11, the first chip 11 and the storage structure 13 can be heat dissipated from one side of the interposer 10 along the first direction D1, and the second chip 12 can be heat dissipated from another side of the interposer 10 along the first direction D1, and the overall heat dissipation performance of the package structure is improved, which helps to further extend the service life of the package structure. Meanwhile, since the projection of the second chip 12 on the second main surface covers the projection of the first chip 11 on the second main surface and the projection of the storage structure 13 on the second main surface (i.e., the area of the second chip 12 is greater than or equal to the sum of the area of the first chip 11 and the area of the storage structure 13), i.e., the second chip 12 with larger area is arranged on the side of the interposer 10 facing away from the first chip 11 with smaller area, on the one hand, the horizontal area of the package structure can be reduced, so that the storage structure 13 and a plurality of chips can be integrated in a limited space, and the integration degree of the package structure is improved, and the functionality of the package structure is expanded; on the other hand, the second chip 12 serves as an area carrier, and the second chip 12 and the interposer 10 jointly bear the first chip 11 and the storage structure 123 located above the interposer 10, which also helps to reduce deformations such as bending, etc. of the interposer 10, so that the performance of the package structure is further improved.

In order to further improve the integration degree of the package structure, in one example, the package structure also includes a third chip located on the first main surface of the interposer 10, and the first chip 11, the third chip, and the storage structure 13 are arranged in a direction parallel to the first main surface, i.e., the first chip 11, the third chip, and the storage structure 13 are tiled on the first main surface of the interposer 10, and the projection of the second chip 12 on the second main surface continuously covers the projection of the first chip 11 on the second main surface, the projection of the third chip on the second main surface, and the projection of the storage structure 13 on the second main surface. Wherein the first chip 11 and the third chip may be chips having the same structure and function; or, the structures and functions of the first chip 11 and the third chip are different.

In another example, the package structure further includes a fourth chip located on the first main surface of the interposer 10, and the fourth chip (not shown) is mounted along the first direction D1 on the surface of the first chip 11 facing away from the interposer 10, and the fourth chip is electrically connected with the first chip and/or the interposer 10, and the surface of the fourth chip facing away from the first chip 11 is flush with the surface of the storage structure 13 facing away from the interposer 10, to improve the heat dissipation performance of the package structure, meanwhile, improve the overall flatness of the package structure.

In other embodiments, in the package structure, a plurality of functional chips and a plurality of storage structures may be arranged on the first main surface of the interposer 10, and at least a partial number of the functional chips and a partial number of the storage structures are tiled on the first main surface of the interposer 10, and the projection of the second chip 12 on the second main surface continuously covers the projections of all functional chips on the second main surface and the projections of all storage structures on the second main surface, to further improve the integration degree of the package structure and expand the functionality of the package structure.

In some embodiments, the second chip 12 includes a front surface and a back surface distributed opposed to each other along the first direction D1, and the functional area 121 of the second chip 12 is located on the front surface of the second chip 12; and the second chip 12 is hybrid bonded on the second main surface of the interposer 10, and the front surface of the second chip 12 faces the interposer 10.

In some embodiments, by mounting the second chip 12 onto the second main surface of the interposer 10 using the manner of hybrid bonding, it not only helps to simplify the manufacturing process of the package structure, but also reduces the dimensions of the package structure along the first direction D1, thereby facilitating further miniaturization of the package structure. The functional area 121 of the second chip 12 faces the interposer 10, which helps to shorten the connection distances between the second chip 12 and the interposer 10, the first chip 11, as well as the storage structure 13, thereby further simplifying the manufacturing process of the package structure. Moreover, orienting the functional area 121 of the second chip 12 toward the interposer 10 also helps to protect the functional area 121 and prevent damage to the functional area 121 from subsequent processes. In one example, the functional area 121 may be exposed on the surface of the second chip 12 facing the interposer 10.

In some embodiments, the package structure further includes: a first vertical interconnection structure passing through the interposer 10 at least along the first direction D1, one end of the first vertical interconnection structure is electrically connected with the first chip 11 and another end is electrically connected with the second chip 12; and a second vertical interconnection structure passing through the interposer 10 at least along the first direction D1, one end of the second vertical interconnection structure is electrically connected with the storage structure 13, and another end is electrically connected with the second chip 12.

In some embodiments, the first vertical interconnection structure includes a first conductive connection pillar 151 passing through the interposer 10 along the first direction D1, a first solder pad 201 located on a side of the first conductive connection pillar 151 facing the first chip D1, a first internal interconnection solder ball 211 located on the first solder pad 201, and a first metal layer 171 located on a side of the first conductive connection pillar 151 facing the second chip 12, and the first internal interconnection solder ball 211 is electrically connected with the first chip 11; and the second vertical interconnection structure includes a second conductive connection pillar 152 passing through the interposer 10 along the first direction D1, a second solder pad 202 located on a side of the second conductive connection pillar 152 facing the storage structure 13, a second internal interconnection solder ball 212 located on the second solder pad 202, and a second metal layer 172 located on a side of the second conductive connection pillar 152 facing the second chip 12, and the second internal interconnection solder ball 212 is electrically connected with the storage structure 13.

In some embodiments, the interposer 10 includes an interposer body and a line layer 101 located within the interposer body, and the line layer 101 is a high-density wiring layer, and the line layer 101 is electrically connected with the first vertical interconnection structure and the second vertical interconnection structure, respectively.

In one example, the package structure further includes a bonding dielectric layer 19 covering on the second main surface of the interposer 10, and the first metal layer 171 and the second metal layer 172 are located within the bonding dielectric layer 19. The second chip 12 is bonded to the bonding dielectric layer 19, the first metal layer 171, and the second metal layer 172 through a manner of hybrid bonding.

By arranging the first vertical interconnection structure, electrical interconnection between the first chip 11 and the second chip 12 is able to be achieved, i.e., the first chip 11 is electrically connected with the second chip 12 through the first internal interconnection solder ball 211, the first solder pad 201, the first conductive connection pillar 151, and the first metal layer 171 in sequence to achieve electrical signal transmission between the first chip 11 and the second chip 12, thereby expanding the functionality of the package structure. By arranging the second vertical interconnection structure, electrical interconnection between the storage structure 13 and the second chip 12 is able to be achieved, i.e., the storage structure 13 is electrically connected with the second chip 12 through the second internal interconnection solder ball 212, the second solder pad 202, the second conductive connection pillar 152, and the second metal layer 172 in sequence to achieve signal transmission between the storage structure 13 and the second chip 12, thereby further expanding the functionality of the package structure. In one example, the second chip 12 further includes a peripheral area distributed around the outer perimeter of the functional area 121, and the peripheral has in it a wiring layer, and the wiring layer electrically connects the first metal layer 171 and the functional area as well as the second metal layer 172.

In some embodiments, the package structure further includes: a third vertical interconnection structure continuously passing through the interposer 10 and the second chip 12 at least along the first direction D1, and the third vertical interconnection structure is electrically connected with the first chip 11; and a fourth vertical interconnection structure continuously passing through the interposer 10 and the second chip 12 at least along the first direction D1, and the fourth vertical interconnection structure is electrically connected with the storage structure 13.

In some embodiments, the third vertical interconnection structure includes a third conductive connection pillar 161 passing through the interposer 10, the bonding dielectric layer 19, and the second chip 12 along the first direction D1, a third solder pad 203 located on a side of the third conductive connection pillar 161 facing the first chip 11, a third internal interconnection solder ball 213 located on the third solder pad 203, and a first lead out solder ball 141 located on a surface of the second chip 12 facing away from the interposer 10; and the fourth vertical interconnection structure includes a fourth conductive connection pillar 162 passing through the interposer 10, the bonding dielectric layer 19, and the second chip 12 along the first direction D1, a fourth solder pad 204 located on a side of the fourth conductive connection pillar 162 facing the storage structure 13, a fourth internal interconnection solder ball 214 located on the fourth solder pad 204, and a second lead out solder ball 142 located on a surface of the second chip 12 facing away from the interposer 10.

In some embodiments, through the third vertical interconnection structure, signals in the first chip 11 can be led out or control signals can be transmitted to the first chip 11, for example, signals in the first chip 11 can be led out sequentially through the third internal interconnection solder ball 213, the third solder pad 203, the third conductive connection pillar 161, and the first lead out solder ball 141, thereby facilitating independent control of the first chip 11 to further expand the functionality of the package structure. Through the fourth vertical interconnection structure, signals in the storage structure 13 can be led out or control signals can be transmitted to the storage structure 13, for example, signals in the storage structure can be sequentially led out through the fourth internal interconnection solder ball 214, the fourth solder pad 204, the fourth conductive connection pillar 162, and the second lead out solder ball 142, thereby facilitating independent control of the storage structure 13 to further expand the functionality of the package structure.

In order to further simplify the manufacturing process of the package structure and reduce the process difficulty of the package structure, in some embodiments, the first vertical interconnection structure, the second vertical interconnection structure, the third vertical interconnection structure, and the fourth vertical interconnection structure are designed at suitable positions along the second direction D2 according to different requirements. In one example, the first vertical interconnection structure and the second vertical interconnection structure are distributed along the second direction D2 on opposite sides of the line layer 101 in the interposer 10, and the third vertical interconnection structure is located on the side of the first vertical interconnection structure facing away from the line layer 101 along the second direction D2, and the fourth vertical interconnection structure is located on the side of the second vertical interconnection structure facing away from the line layer 101 along the second direction D2. In another example, the first vertical interconnection structure and the second vertical interconnection structure are located on the same side of the line layer 101 in the interposer 10, and the third vertical interconnection structure and the fourth vertical interconnection structure are located on the same side of the line layer 101 in the interposer 10, and the first vertical interconnection structure and the third vertical interconnection structure are distributed along the second direction D2 on opposite sides of the line layer 101, and the second vertical interconnection structure and the fourth vertical interconnection structure are distributed along the second direction D2 on opposite sides of the line layer 101.

In some embodiments, the package structure further includes: a first internal interconnection structure including a fifth solder pad 205 located on the first main surface of the interposer 10 and a fifth internal interconnection solder ball 215 located on the fifth solder pad 205, the fifth solder pad 205 is electrically connected with the line layer 101, and the fifth internal interconnection solder ball 215 is electrically connected with the first chip 11; and a second internal interconnection structure including a sixth solder pad 206 located on the first main surface of the interposer 10 and a sixth internal interconnection solder ball 216 located on the sixth solder pad 206, the sixth solder pad 206 is electrically connected with the line layer 101, and the sixth internal interconnection solder ball 216 is electrically connected with the storage structure 13.

For example, the electrical connection between the first chip 11 and the line layer 101 within the interposer 10 is achieved through the fifth solder pad 205 and the fifth internal interconnection solder ball 215, and the electrical connection between the storage structure 13 and the line layer 101 within the interposer 10 is achieved through the sixth solder pad 206 and the sixth internal interconnection solder ball 216. In some embodiments, the fifth solder pad 205 and the sixth solder pad 206 are directly arranged on the first main surface of the interposer 10, and the line layer 101 is electrically connected with the first chip 11 through the fifth solder pad 205, and the line layer 101 is electrically connected with the storage structure 13 through the sixth solder pad 206.

Since the first chip 11 and the second chip 12 are electrically connected through the first vertical interconnection structure, the first chip 11 and the line layer 101 in the interposer 10 are electrically connected through the first internal interconnection structure, and the storage structure 13 and the second chip 12 are electrically connected through the second vertical interconnection structure, and the storage structure and the line layer 101 in the interposer 10 are electrically connected through the second internal interconnection structure, so that the electrical connection between the second chip 12 and the interposer 10 can be achieved through the first vertical interconnection structure, the first chip 11, and the first internal interconnection structure, and the electrical connection between the second chip 12 and the interposer 10 can be achieved through the second vertical interconnection structure, the storage structure 13, and the second internal interconnection structure, and there is no need to arrange an electrical connection line that direct electrically connects the second chip 12 with the interposer 10, which helps to further optimize the line arrangement inside the package structure and reduce the parasitic capacitance effect inside the packaging structure.

In some embodiments, the package structure further includes: a molding layer 18, located on the first main surface of the interposer 10, and the molding layer 18 continuously molds the first chip 11 and the storage structure 13.

In some embodiments, the surface of the first chip 11 facing away from the interposer 10 along the first direction D1 is flush with the surface of the storage structure 13 facing away from the interposer 10 along the first direction D1.

In some embodiments, the molding layer 18 exposes the surface of the first chip 11 facing away from the interposer 10 and the surface of the storage structure 13 facing away from the interposer 10.

In one example, by making the surface of the first chip 11 facing away from the interposer 10 flush with the surface of the storage structure 13 facing away from the interposer 10, the surface of the first chip 11 facing away from the interposer 10 and the surface of the storage structure 13 facing away from the interposer 10 can be exposed through the molding layer 18, to facilitate heat dissipation for the first chip 11 and the storage structure 13. Wherein the material of the molding layer 18 may be epoxy resin molding material, organic silicon molding material, polyimide molding material, or phenolic resin molding material.

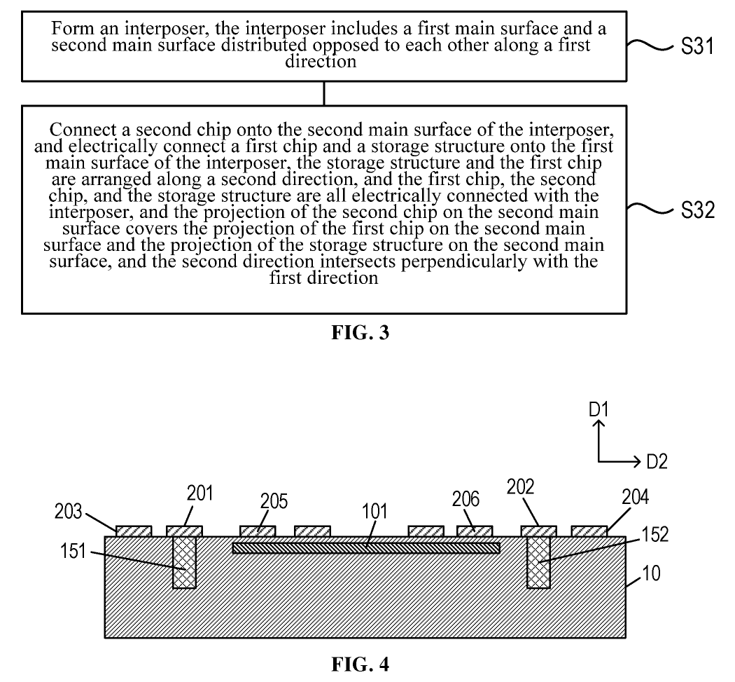

The present embodiment also provides a method for forming a package structure, FIG. 3 is a flowchart of the method for forming a package structure in the embodiment of the present disclosure, and for the schematic diagrams of the package structure formed by the present embodiment, reference can be made to FIGS. 1 and 2. As shown in FIGS. 1-3, the method for forming the package structure includes the following steps.

Step S31: Forming an interposer 10, the interposer 10 includes a first main surface and a second main surface distributed opposed to each other along a first direction D1.

Step S32: Connecting the second chip 12 onto the second main surface of the interposer 10, and electrically connecting the first chip 11 and the storage structure 13 onto the first main surface of the interposer 10, the storage structure 13 and the first chip 11 are arranged along the second direction D1, and the first chip 11, the second chip 12, and the storage structure 13 are all electrically connected with the interposer 10, and the projection of the second chip 12 on the second main surface covers the projection of the first chip 11 on the second main surface and the projection of the storage structure 13 on the second main surface, and the second direction D2 intersects perpendicularly with the first direction D1.

In order to further increase the integration degree of the package structure, in some embodiments, the specific steps for connecting the second chip 12 onto the second main surface of the interposer 10 and electrically connecting the first chip 11 and the storage structure 13 onto the first main surface of the interposer 10 include: Connecting the second chip 12 onto the second main surface of the interposer 10, and electrically connecting the first chip 11, the third chip, and the storage structure 13 onto the first main surface of the interposer 10, the first chip 11, the third chip, and the storage structure 13 are arranged along a direction parallel to the first main surface, and the projection of the second chip 12 on the second main surface continuously covers the projection of the first chip 11 on the second main surface, the projection of the third chip on the second main surface, and the projection of the storage structure 13 on the second main surface.

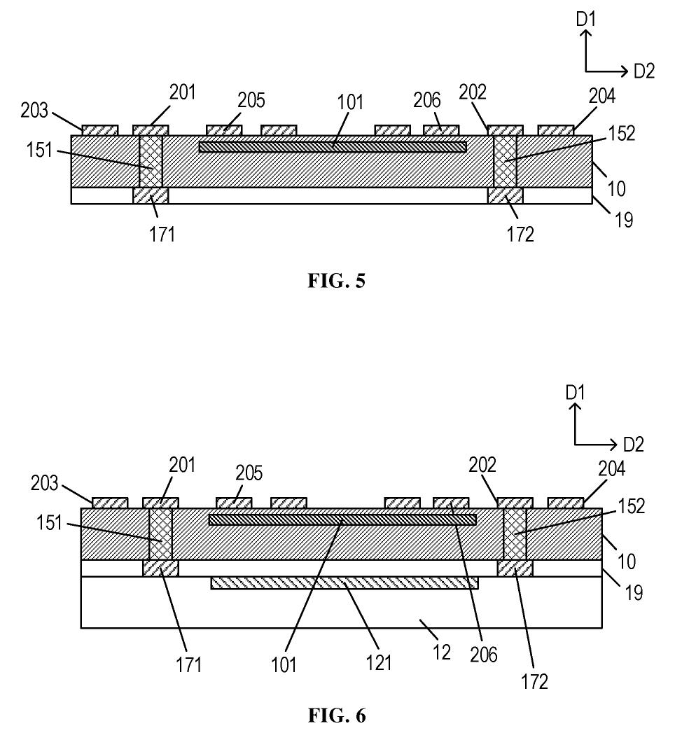

FIG. 4 is a structural schematic diagram of an interposer in an embodiment of the present disclosure; FIG. 5 is a structural schematic diagram after forming the first vertical interconnection structure and the second vertical interconnection structure in an embodiment of the present disclosure. In some embodiments, before connecting the second chip 12 onto the second main surface of the interposer 10 and electrically connecting the first chip 11 and the storage structure 13 onto the first main surface of the interposer 10, the method further includes the following steps: forming a first solder pad 201 and a second solder pad 202 located on the first main surface of the interposer 10 and a first conductive connection pillar 151 and a second conductive connection pillar 152 passing through the interposer 10 along the first direction D1, the first conductive connection pillar 151 is electrically connected with the first solder pad 201 and the second conductive connection pillar 152 is electrically connected with the second solder pad 202; and forming, on the second main surface of the interposer 10, a bonding dielectric layer 19 and a first metal layer 171 and a second metal layer 172 passing through the bonding dielectric layer along the first direction D1, the first metal layer 171 is electrically connected with the first conductive connection pillar 151, and the second metal layer 172 is electrically connected with the second conductive connection pillar 152.

In some embodiments, the specific steps for forming a first solder pad 201 and a second solder pad 202 located on the first main surface of the interposer 10 and a first conductive connection pillar 151 and a second conductive connection pillar 152 passing through the interposer 10 along the first direction D1, the first conductive connection pillar 151 is electrically connected with the first solder pad 201 and the second conductive connection pillar 152 is electrically connected with the second solder pad 202 include: providing an interposer 10; forming a first blind hole and a second blind hole arranged along the second direction D2 within the interposer 10, and both the first blind hole and the second blind hole extend from the first main surface of the interposer 10 toward the interior of the interposer; forming a first conductive connection pillar 151 within the first blind hole and forming a second conductive connection pillar 152 within the second blind hole; and forming, on the first main surface of the interposer 10, a first solder pad 201 electrically connected with the first conductive connection pillar 151 and a second solder pad 202 electrically connected with the second conductive connection pillar 152; and thinning the interposer 10 to expose the surface of the first conductive connection pillar 151 facing away from the first solder pad 201 and the surface of the second conductive connection pillar 152 facing away from the second solder pad 202.

For example, the interposer 10 is provided, and the interposer includes an interposer body and the line layer 101 inside the interposer body. The top surface of the interposer body is used as the first main surface of the interposer 10, a first blind hole and a second blind hole extending along the first direction D1 are formed from the first main surface into the interposer body, and a first conductive connection pillar 151 is formed within the first blind hole, and a second conductive connection pillar 152 is formed within the second blind hole, and a plurality of solder pads are formed on the first main surface of the interposer 10, and a part of the solder pads located on one side of the line layer 101 along the second direction D2 are used as the first solder pad 201, and a part of the solder pads located on another side of the line layer 101 along the second direction D2 are used as the second solder pad 202, and the first solder pad 201 is in contact with and electrically connected with the first conductive connection pillar 151, and the second solder pad 202 is in contact with and electrically connected with the second conductive connection pillar 152, as shown in FIG. 4. Thinning treatment is performed on the interposer body to expose the surface of the first conductive connection pillar 151 facing away from the first solder pad 201 and the surface of the second conductive connection pillar 152 facing away from the second solder pad 202, and the surface of the thinned interposer body facing away from the first solder pad 201 is used as the second main surface of the interposer 10. Wherein the method for exposing the surface of the first conductive connection pillar 151 and the surface of the second conductive connection pillar 152 may be BVR (Backside via reveal) or BFR (Backside via flatness reveal). Next, a bonding dielectric layer 19, and a first metal layer 171 and a second metal layer 172 passing through the bonding dielectric layer along the first direction D1 are formed on the second main surface of the interposer 10, and the first metal layer 171 is electrically connected with the first conductive connection pillar 151, and the second metal layer 172 is electrically connected with the second conductive connection pillar 152, as shown in FIG. 5.

FIG. 6 is a structural schematic diagram after bonding the second chip to the second main surface of the interposer in an embodiment of the present disclosure. In some embodiments, the second chip 12 includes a front surface and a back surface distributed opposed to each other along the first direction, and the functional area 121 of the second chip 12 is located on the front surface of the second chip; the specific steps for connecting the second chip 12 onto the second main surface of the interposer 10 and electrically connecting the first chip 11 and the storage structure 13 onto the first main surface of the interposer 10 include: hybrid bonding the second chip 12 with the interposer 10 in a direction in which the front surface of the second chip 12 faces the bonding dielectric layer 19, as shown in FIG. 6, the second chip 12 is bonded and electrically connected with the first metal layer 171 and the second metal layer 172; and soldering the first chip 11 and the storage structure 13 onto the first main surface of the interposer 10.

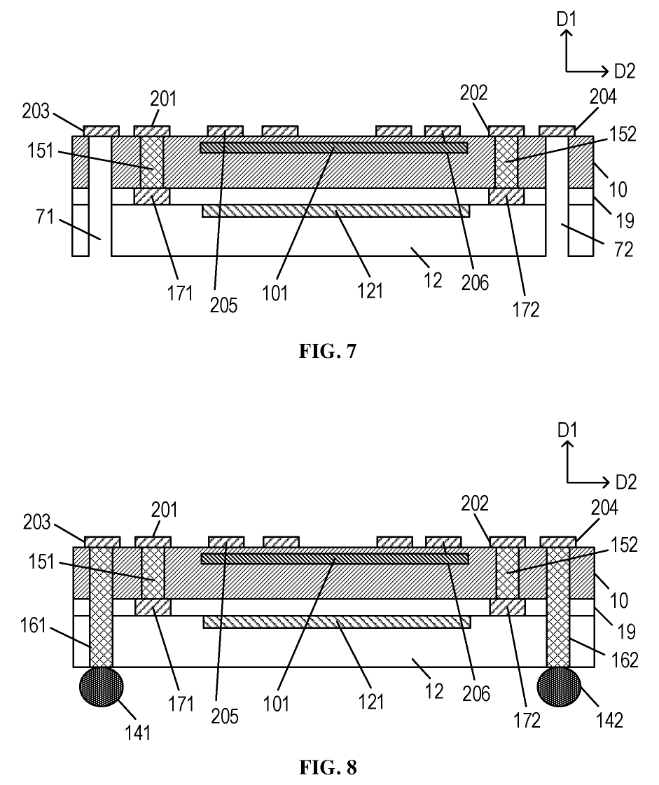

FIG. 7 is a structural schematic diagram after forming the first through-hole and the second through-hole in an embodiment of the present disclosure, FIG. 8 is a structural schematic diagram after forming the third vertical interconnection structure and the fourth vertical interconnection structure in an embodiment of the present disclosure. In some embodiments, before soldering the first chip 11 and the storage structure 13 onto the first main surface of the interposer 10, the method further includes the following steps: forming a third vertical interconnection structure and a fourth vertical interconnection structure both continuously passing through the interposer 10, the bonding dielectric layer 19, and the second chip 12 along the first direction D1, and the third vertical interconnection structure and the fourth vertical interconnection structure are arranged at intervals along the second direction D2.

In some embodiments, the first main surface of the interposer 10 is also provided with a third solder pad 203 and a fourth solder pad 204; the specific steps for forming the third vertical interconnection structure and the fourth vertical interconnection structure both continuously passing through the interposer 10, the bonding dielectric layer 19, and the second chip 12 along the first direction D1 include: forming a third conductive connection pillar 161 sequentially passing through the second chip 12, the bonding dielectric layer 19, and the interposer 10 along the first direction D1 and electrically connected with the third solder pad 203, and forming a fourth conductive connection pillar 162 sequentially passing through the second chip 12, the bonding dielectric layer 19, and the interposer 10 along the first direction D1 and electrically connected with the fourth solder pad 204, to form the third vertical interconnection structure including the third solder pad and the third conductive connection pillar, and to form the fourth vertical interconnection structure including the fourth solder pad and the fourth conductive connection pillar.

In some embodiments, the specific steps for forming a third conductive connection pillar 161 sequentially passing through the second chip 12, the bonding dielectric layer 19, and the interposer 10 along the first direction D1 and electrically connected with the third solder pad 203, and forming a fourth conductive connection pillar 162 sequentially passing through the second chip 12, the bonding dielectric layer 19, and the interposer 10 along the first direction D1 and electrically connected with the fourth solder pad 204 include: etching starting from the surface of the second chip 12 facing away from the interposer 10, forming a first through-hole 71 sequentially passing through the second chip 12, the bonding dielectric layer 19, and the interposer 10 along the first direction D1 and exposing the third solder pad 203, and forming a second through-hole 72 sequentially passing through the second chip 12, the bonding dielectric layer 19, and the interposer 10 along the first direction D1 and exposing the fourth solder pad 204, as shown in FIG. 7; and filling conductive material into the first through-hole 71 and the second through-hole 72, forming the third conductive connection pillar 161 within the first through-hole 71, and forming the fourth conductive connection pillar 162 within the second through-hole 72, as shown in FIG. 8.

In some embodiments, before soldering the first chip 11 and the storage structure 13 onto the first main surface of the interposer 10, the method further includes the following steps: forming a first lead out solder ball 141 located on the surface of the third conductive connection pillar 161 facing away from the third solder pad 203, and forming a second lead out solder ball 142 located on the surface of the fourth conductive connection pillar 162 facing away from the fourth solder pad 204, as shown in FIG. 8.

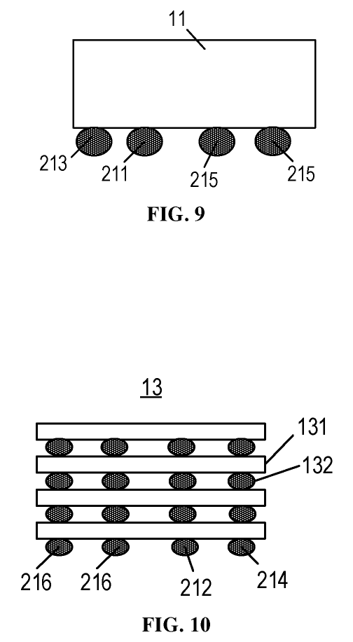

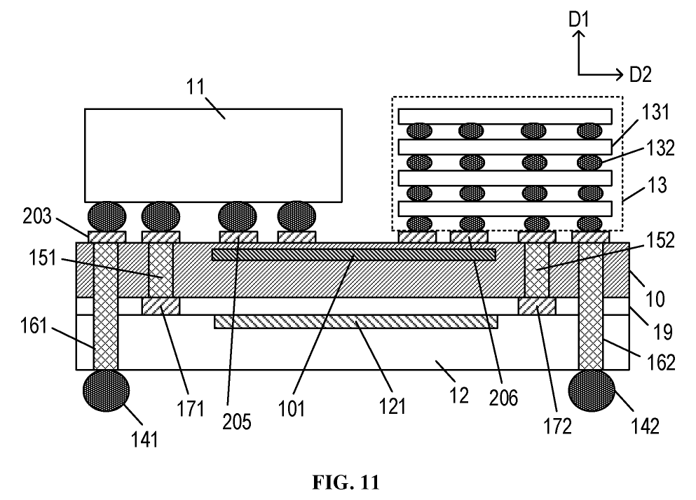

FIG. 9 is a structural schematic diagram of the first chip in an embodiment of the present disclosure, FIG. 10 is a structural schematic diagram of the storage structure in an embodiment of the present disclosure, FIG. 11 is a structural schematic diagram after mounting the first chip and the storage structure onto the first main surface of the interposer in an embodiment of the present disclosure. In some embodiments, the first main surface of the interposer 10 is also provided with a fifth solder pad 205 and a sixth solder pad 206 electrically connected with the interposer 10; the specific steps for soldering the first chip 11 and the storage structure 13 onto the first main surface of the interposer 10 include: forming a first internal interconnection solder ball 211, a third internal interconnection solder ball 213, and a fifth internal interconnection solder ball 215 on the surface of the first chip 11 (as shown in FIG. 9), and forming a second internal interconnection solder ball 212, a fourth internal interconnection solder ball 214, and a sixth internal interconnection solder ball 216 on the surface of the storage structure 13 (as shown in FIG. 10); and soldering the first chip 11 and the storage structure onto the first main surface of the interposer 10, such that the first internal interconnection solder ball 211 on the first chip 11 is soldered to the first solder pad 201, the third internal interconnection solder ball 213 is soldered to the third solder pad 203, and the fifth internal interconnection solder ball 215 is soldered to the fifth solder pad 205, and such that the second internal interconnection solder ball 212 on the storage structure 13 is soldered to the second solder pad 202, the fourth internal interconnection solder ball 214 is soldered to the fourth solder pad 204, and the sixth internal interconnection solder ball 216 is soldered to the sixth solder pad 206, as shown in FIG. 11.

In some embodiments, the surface of the first chip 11 facing away from the interposer 10 is flush with the surface of the storage structure 13 facing away from the interposer 10.

In some embodiments, after soldering the first chip 11 and the storage structure 13 onto the first main surface of the interposer 10, the method further includes the following step: forming a molding layer 18 continuously molding the first chip 11 and the storage structure 13 on the first main surface of the interposer 10, the molding layer 18 exposes the surface of the first chip 11 facing away from the interposer 10 and the surface of the storage structure 13 facing away from the interposer 10, as shown in FIG. 1.

For example, after hybrid bonding the second chip 12 with the bonding dielectric layer 19, the first metal layer 171, and the second metal layer 172 in a direction in which the front surface of the second chip 12 faces the interposer 10, the structure shown in FIG. 6 is obtained. Next, etching is started from the surface of the second chip 12 facing away from the interposer 10 (i.e., the back surface of the second chip 12) to form a first through-hole 71 and a second through-hole 72 continuously passing through the second chip 12 and the interposer 10 along the first direction D1, as shown in FIG. 7. Conductive material such as copper or tungsten, etc., is filled into the first through-hole and the second through-hole to form the third conductive connection pillar 161 and the fourth conductive connection pillar 162, as shown in FIG. 8. Subsequently, a first lead out solder ball 141 located on the surface of the third conductive connection pillar 161 facing away from the third solder pad 203 is formed, and a second lead out solder ball 142 located on the surface of the fourth conductive connection pillar 162 facing away from the fourth solder pad 204 is formed, as shown in FIG. 8. Next, the first chip 11 formed with the first internal interconnection solder ball 211, the third internal interconnection solder ball 21, and the fifth internal interconnection solder ball 215 is soldered onto the first main surface of the interposer 10, and the storage structure 13 formed with the second internal interconnection solder ball 212, the fourth internal interconnection solder ball 214, and the sixth internal interconnection solder ball 216 is soldered onto the first main surface of the interposer 10, as shown in FIG. 11. Subsequently, the first chip 11 and the storage structure 13 are molded using a molding material such as epoxy resin, etc., to form the molding layer 18, as shown in FIG. 1. The molding layer 18 exposes the surface of the first chip 11 facing away from the interposer 10 and the surface of the storage structure 13 facing away from the interposer 10 to facilitate heat dissipation for the first chip 11 and the storage structure 13.

The present embodiment is exemplified by the example of forming the first lead out solder ball and the second lead out solder ball before mounting the first chip and the storage structure onto the first main surface of the interposer. In other embodiments, after forming the molding layer 18 continuously molding the first chip 11 and the storage structure 13 on the first main surface of the interposer 10, the method further includes the following steps: forming a first lead out solder ball 141 on the surface of the third conductive connection pillar 161 facing away from the third solder pad 203, and forming a second lead out solder ball 142 on the surface of the fourth conductive connection pillar 162 facing away from the fourth solder pad 204.

In some embodiments, after mounting the first chip 11 and the storage structure 13 and forming the molding layer 18, a first lead out solder ball 141 is formed on the surface of the third conductive connection pillar 161 facing away from the third solder pad 203, and a second lead out solder ball 142 is formed on the surface of the fourth conductive connection pillar 162 facing away from the fourth solder pad 204, which can prevent the first lead out solder ball 141 and the second lead out solder ball 142 from being affected by the molding process and the mounting process of the first chip and the storage structure.

In the package structure and the method for forming the same provided by the present disclosure, by mounting the first chip and the storage structure on the first main surface of the interposer and arranging the second chip on the second main surface of the interposer, and making the projection of the second chip on the second main surface cover the projection of the first chip on the second main surface and the projection of the storage structure on the second main surface, not only the integration of a plurality of chips and storage structures is achieved within a limited space, and the integration degree and scalability of the package structure are also improved, and the functionality of the package structure is expanded, but also by arranging the second chip with the largest area on the second main surface, the area of the entire package structure is effectively saved, thereby helping to further reduce the size of the package structure. Meanwhile, the first chip and the second chip are arranged on opposite sides of the interposer in the present disclosure, so that heat dissipation can be carried out from the opposite sides of the interposer, respectively, the overall heat dissipation performance of the package structure is improved, which helps to further extend the service life of the package structure.

The above is only some embodiments of the present disclosure, it should be noted that those ordinary skilled in the art may also make several improvements and refinements without departing from the principles of the present disclosure, and these improvements and refinements should also be considered as the protection scope of the present disclosure.

What is claimed is:

1. A package structure, comprising:
an interposer comprising a first main surface and a second main surface opposite to the first main surface along a first direction;
a first chip on the first main surface of the interposer, electrically connected to the interposer;
a storage structure on the first main surface of the interposer, electrically connected to the interposer, wherein the storage structure and the first chip are arranged along a second direction perpendicular to the first direction; and
a second chip on the second main surface of the interposer, electrically connected to the interposer, wherein a projection of the second chip onto the second main surface covers a projection of the first chip onto the second main surface and a projection of the storage structure onto the second main surface.

2. The package structure according to claim 1, wherein:
the second chip comprises a front surface and a back surface opposite to the front surface along the first direction, and a functional area of the second chip is on the front surface; and
the second chip is hybrid bonded to the second main surface of the interposer, such that the front surface faces the interposer.

3. The package structure according to claim 1, further comprising:
a first vertical interconnection structure extending through the interposer at least along the first direction, wherein one end of the first vertical interconnection structure is electrically connected to the first chip and another end is electrically connected to the second chip; and
a second vertical interconnection structure extending through the interposer at least along the first direction, wherein one end of the second vertical interconnection structure is electrically connected to the storage structure and another end is electrically connected to the second chip.

4. The package structure according to claim 3, wherein:
the first vertical interconnection structure comprises a first conductive connection pillar extending through the interposer along the first direction, a first solder pad located on a side of the first conductive connection pillar facing the first chip, a first internal interconnection solder ball located on the first solder pad, a first metal layer located on a side of the first conductive connection pillar facing the second chip, and the first internal interconnection solder ball is electrically connected to the first chip; and
the second vertical interconnection structure comprises a second conductive connection pillar extending through the interposer along the first direction, a second solder pad located on a side of the second conductive connection pillar facing the storage structure, a second internal interconnection solder ball located on the second solder pad, a second metal layer located on a side of the second conductive connection pillar facing the second chip, and the second internal interconnection solder ball is electrically connected to the storage structure.

5. The package structure according to claim 4, further comprising:
a bonding dielectric layer covering the second main surface of the interposer, wherein the first metal layer and the second metal layer are located in the bonding dielectric layer;
a third vertical interconnection structure extending continuously through the interposer, the bonding dielectric layer, and the second chip at least along the first direction, wherein the third vertical interconnection structure is electrically connected to the first chip; and
a fourth vertical interconnection structure extending continuously through the interposer, the bonding dielectric layer, and the second chip at least along the first direction, and the fourth vertical interconnection structure is electrically connected to the storage structure, wherein:
the third vertical interconnection structure comprises a third conductive connection pillar extending through the interposer, the bonding dielectric layer, and the second chip along the first direction, a third solder pad located on a side of the third conductive connection pillar facing the first chip, a third internal interconnection solder ball located on the third solder pad, and a first lead out solder ball located on a surface of a side of the second chip facing away from the interposer; and
the fourth vertical interconnection structure comprises a fourth conductive connection pillar extending through the interposer, the bonding dielectric layer, and the second chip along the first direction, a fourth solder pad located on a side of the fourth conductive connection pillar facing the storage structure, a fourth internal interconnection solder ball located on the fourth solder pad, and a second lead out solder ball located on the surface of the side of the second chip facing away from the interposer.

6. The package structure according to claim 4, further comprising:
a first internal interconnection structure comprising a fifth solder pad located on the first main surface of the interposer and a fifth internal interconnection solder ball located on the fifth solder pad, wherein the fifth solder pad is electrically connected to a line layer, and the fifth internal interconnection solder ball is electrically connected to the first chip; and
a second internal interconnection structure comprising a sixth solder pad located on the first main surface of the interposer and a sixth internal interconnection solder ball located on the sixth solder pad, wherein the sixth solder pad is electrically connected to the line layer, and the sixth internal interconnection solder ball is electrically connected to the storage structure.

7. The package structure according to claim 1, further comprising:
a third chip on the first main surface of the interposer, wherein the first chip, the third chip, and the storage structure are arranged along a direction parallel to the first main surface, a projection of the second chip onto the second main surface continuously covers a projection of the first chip on the second main surface, a projection of the third chip onto the second main surface, and a projection of the storage structure onto the second main surface.

8. The package structure according to claim 1, further comprising:
a molding layer on the first main surface of the interposer, wherein the molding layer continuously molds the first chip and the storage structure.

9. The package structure according to claim 8, wherein a surface of the first chip facing away from the interposer along the first direction is flush with a surface of the storage structure facing away from the interposer along the first direction.

10. The package structure according to claim 8, wherein the molding layer exposes a surface of the first chip facing away from the interposer and a surface of the storage structure facing away from the interposer.

11. The package structure according to claim 1, wherein the storage structure is a high bandwidth memory.

12. A method for forming a package structure, comprising:
forming an interposer, the interposer comprises a first main surface and a second main surface opposite to the first main surface along a first direction; and
electrically connecting a first chip and a storage structure onto the first main surface of the interposer, and connecting a second chip onto the second main surface of the interposer,
wherein:
the storage structure and the first chip are arranged along a second direction perpendicular to the first direction,
the first chip, the second chip, and the storage structure are all electrically connected to the interposer, and
a projection of the second chip onto the second main surface covers a projection of the first chip onto the second main surface and a projection of the storage structure onto the second main surface.

13. The method for forming a package structure according to claim 12, wherein the electrically connecting a first chip and a storage structure onto the first main surface of the interposer, and connecting a second chip onto the second main surface of the interposer comprise:
electrically connecting the first chip, a third chip, and the storage structure onto the first main surface of the interposer, and connecting the second chip onto the second main surface of the interposer,
wherein:
the first chip, the third chip, and the storage structure are arranged along a direction parallel to the first main surface,
a projection of the second chip onto the second main surface continuously covers a projection of the first chip onto the second main surface, a projection of the third chip onto the second main surface, and a projection of the storage structure onto the second main surface.

14. The method for forming a package structure according to claim 12, wherein before electrically connecting a first chip and a storage structure onto the first main surface of the interposer, and connecting a second chip onto the second main surface of the interposer, the method further comprises:
forming a first solder pad and a second solder pad on the first main surface of the interposer, and forming a first conductive connection pillar and a second conductive connection pillar extending through the interposer along the first direction,
wherein the first conductive connection pillar is electrically connected to the first solder pad, and the second conductive connection pillar is electrically connected to the second solder pad; and
forming, on the second main surface of the interposer, a bonding dielectric layer and a first metal layer, and forming a second metal layer extending through the bonding dielectric layer along the first direction,
wherein the first metal layer is electrically connected to the first conductive connection pillar, and the second metal layer is electrically connected to the second conductive connection pillar.

15. The method for forming a package structure according to claim 14, wherein the forming the first solder pad and the second solder pad on the first main surface of the interposer, and forming the first conductive connection pillar and the second conductive connection pillar extending through the interposer along the first direction, wherein the first conductive connection pillar is electrically connected to the first solder pad, and the second conductive connection pillar is electrically connected to the second solder pad, comprise:
providing the interposer;
forming a first blind hole and a second blind hole arranged along the second direction in the interposer, wherein both the first blind hole and the second blind hole extend from the first main surface of the interposer toward an interior of the interposer;
forming a first conductive connection pillar in the first blind hole and forming a second conductive connection pillar in the second blind hole, and forming, on the first main surface of the interposer, a first solder pad electrically connected to the first conductive connection pillar and a second solder pad electrically connected to the second conductive connection pillar; and
thinning the interposer to expose a surface of the first conductive connection pillar facing away from the first solder pad and a surface of the second conductive connection pillar facing away from the second solder pad.

16. The method for forming a package structure according to claim 14, wherein the second chip comprises a front surface and a back surface distributed opposite to the front surface along the first direction, and a functional area of the second chip is located on the front surface; wherein the electrically connecting the first chip and the storage structure onto the first main surface of the interposer, and connecting the second chip onto the second main surface of the interposer, further comprise:
hybrid bonding the second chip to the interposer in a direction in which the front surface of the second chip faces the bonding dielectric layer; and
soldering the first chip and the storage structure to the first main surface of the interposer.

17. The method for forming a package structure according to claim 16, wherein before soldering the first chip and the storage structure to the first main surface of the interposer, the method further comprises:
forming a third vertical interconnection structure and a fourth vertical interconnection structure each extending continuously through the interposer, the bonding dielectric layer, and the second chip along the first direction, wherein the third vertical interconnection structure and the fourth vertical interconnection structure are arranged at intervals along the second direction.

18. The method for forming a package structure according to claim 17, wherein the first main surface of the interposer is also provided with a third solder pad and a fourth solder pad; wherein the forming the third vertical interconnection structure and the fourth vertical interconnection structure each extending continuously through the interposer, the bonding dielectric layer, and the second chip along the first direction, further comprise:
forming a third conductive connection pillar extending through the second chip, the bonding dielectric layer, and the interposer along the first direction and electrically connected to the third solder pad, and forming a fourth conductive connection pillar extending through the second chip, the bonding dielectric layer, and the interposer along the first direction and electrically connected to the fourth solder pad, to form the third vertical interconnection structure comprising the third solder pad and the third conductive connection pillar, and to form the fourth vertical interconnection structure comprising the fourth solder pad and the fourth conductive connection pillar,
wherein the forming the third conductive connection pillar extending through the second chip, the bonding dielectric layer, and the interposer along the first direction and electrically connected to the third solder pad, and forming the fourth conductive connection pillar extending through the second chip, the bonding dielectric layer, and the interposer along the first direction and electrically connected to the fourth solder pad, further comprise:
etching from a surface of the second chip facing away from the interposer, forming a first through-hole extending through the second chip, the bonding dielectric layer, and the interposer along the first direction and exposing the third solder pad, and forming a second through-hole extending through the second chip, the bonding dielectric layer, and the interposer along the first direction and exposing the fourth solder pad; and
filling a conductive material into the first through-hole and the second through-hole, forming the third conductive connection pillar in the first through-hole, and forming the fourth conductive connection pillar in the second through-hole.

19. The method for forming a package structure according to claim 18, wherein before soldering the first chip and the storage structure onto the first main surface of the interposer, the method further comprises:
forming a first lead out solder ball on a surface of the third conductive connection pillar facing away from the third solder pad, and forming a second lead out solder ball on a surface of the fourth conductive connection pillar facing away from the fourth solder pad.

20. The method for forming a package structure according to claim 18, wherein the first main surface of the interposer is also provided with a fifth solder pad and a sixth solder pad electrically connected to the interposer; wherein the soldering the first chip and the storage structure onto the first main surface of the interposer, further comprise:
forming a first internal interconnection solder ball, a third internal interconnection solder ball, and a fifth internal interconnection solder ball on a surface of the first chip, and forming a second internal interconnection solder ball, a fourth internal interconnection solder ball, and a sixth internal interconnection solder ball on a surface of the storage structure; and
soldering the first chip and the storage structure to the first main surface of the interposer, so that the first internal interconnection solder ball on the first chip is soldered to the first solder pad, the third internal interconnection solder ball is soldered to the third solder pad, and the fifth internal interconnection solder ball is soldered to the fifth solder pad, and so that the second internal interconnection solder ball on the storage structure is soldered to the second solder pad, the fourth internal interconnection solder ball is soldered to the fourth solder pad, and the sixth internal interconnection solder ball is soldered to the sixth solder pad,
wherein:
a surface of the first chip facing away from the interposer is flush with a surface of the storage structure facing away from the interposer; or
after soldering the first chip and the storage structure to the first main surface of the interposer, the method further comprises:
forming, on the first main surface of the interposer, a molding layer that continuously molds the first chip and the storage structure, wherein the molding layer exposes the surface of the first chip facing away from the interposer and the surface of the storage structure facing away from the interposer; and
forming a first lead out solder ball located on a surface of the third conductive connection pillar facing away from the third solder pad, and forming a second lead out solder ball located on a surface of the fourth conductive connection pillar facing away from the fourth solder pad.
